(19) United States
(12) Patent Application Publication
(10) Pub. No.: US 2018/0158747 A1
(43) Pub. Date: Jun. 7, 2018

(54) HEAT SINK

(71) Applicant: Panasonic Intellectual Property Management co, Ltd., Osaka (JP)

(72) Inventors: ATSUSHI TANAKA, Osaka (JP); NAOMI NISHIKI, Kyoto (JP); HIDETOSHI KITAURA, Osaka (JP); RYOU KUWABARA, Osaka (JP); TAKESHI NISHIKAWA, Osaka (JP)

(21) Appl. No.: 15/725,177

(22) Filed: Oct. 4, 2017

(30) Foreign Application Priority Data
Dec. 6, 2016 (JP) 2016-237028

(51) Int. Cl. H01L 23/367; H01L 23/373; H05K 7/20; B32B 9/00; B32B 9/04

(52) U.S. Cl. CPC H01L 23/3672; H01L 23/3735; B32B 2307/302; B32B 9/007; B32B 9/045; H05K 7/20409

(57) ABSTRACT

A graphite heat sink includes plate-shaped fin portions formed of a graphite material, a base portion contacting lower ends of the plate-shaped fin portions and a joining portion between the plate-shaped fin portions and the base portion, in which the plate-shaped fin portions have a thermal conductivity of 1200 W/mk or more and a thickness of 100 μm or more, and the joining portion is formed of metal.

### TECHNICAL FIELD

The technical field relates to a heat sink dissipating heat from a heating element.

### BACKGROUND

In recent years, the heat generated in electric devices is increasing along with the improved performance of electronic devices. It is common that a thermal conductor such as a heat sink is attached to a heat source for dissipating heat from the heat source. Accordingly, heat sinks are increasing in sine along with the increase of the heat generated in the electronic devices. However, a small-sized heat sink that is still capable of dissipating large amounts of heat is necessary for reducing the size and weight of electronic devices, and a heat sink using graphite having a high thermal conductivity is one means.

One example of a heat sink using graphite is one described in WO2015/07 2428 (Patent Literature 1). The heat sink generally includes a base portion contacting the heat source and fin portions for dissipating heat. The heat sink described in Patent Literature 1 uses graphite sheets having a high thermal conductivity for the fin portions to thereby improve heat dissipation properties.

### SUMMARY

In Patent Literature 1, an adhesive layer formed by using a composition containing a polyvinyl acetal resin is used for joining between the fin portions and the base portion. The thermal conductivity of the polyvinyl acetal resin is 1/100 or less of the thermal conductivity of general metals, therefore, it is considered that heat is hardly transmitted from the base portion to the fin portions and it is difficult to secure a sufficient heat transport property as compared with the case where the adhesive layer is made of only metal. As the adhesive layer according to Patent Literature 1 is thus considered to have a smaller thermal conductivity as compared with those of metals as described above, it is necessary to form the adhesive layer to be as thin as possible in order to reduce thermal resistance in the adhesive layer. However, when the thickness of the adhesive layer is reduced, it is likely that adhesive strength in the adhesive layer is also reduced. In this case, there is a possibility that the thin adhesive layer does not have sufficient adhesive strength for fixing the thick fin portions, therefore, the thickness of the fin portions is not capable of being increased, which hinders improvement of heat dissipation properties.

An object of the present disclosure is to provide a heat sink with high heat dissipation properties which solves the related art problems.

In view of the above problems, as well as other concerns, a graphite heat sink according to the present disclosure includes plate-shaped fin portions formed of a graphite material, a base portion contacting lower ends of the plate-shaped fin portions and a joining portion between the plate-shaped fin portions and the base portion, in which the plate-shaped fin portions have a thermal conductivity of 1200 W/mk or more and a thickness of 100 μm or more, and the joining portion is formed of metal.

As the graphite heat sink according to the present disclosure has high heat dissipation properties due to the above structure, the heat sink can be effectively used in apparatuses with a high heat generation density.

According to the present disclosure, a heat sink with high heat dissipation properties is provided.

### BRIEF DESCRIPTION OF THE DRAWINGS

FIG. 1 is a schematic cross-sectional view showing a heat sink according to an example of the present disclosure;

FIG. 2 is a schematic cross-sectional view showing a base portion used in the example of the present disclosure; and

FIG. 3 is a schematic cross-sectional view showing a device for a verification experiment for heat dissipation properties.

### DESCRIPTION OF EMBODIMENTS

Hereinafter, an embodiment of the present disclosure will be explained.

### <Base Portion>

A base portion is provided for holding fin portions. It is desirable that a material having a high thermal conductivity is used as a material for the base portion so as to transmit heat from a heat source to fin portions effectively. As materials for the base portion, for example, metals such as aluminum and copper, carbon, resin and so on can be used, however, materials are not limited to the above and any arbitrary materials having high conductivities may be used.

### <Fin Portions>

The fin portions aim to carry heat in the base portion and dissipate heat to the air, which requires high heat transport properties. The heat conductivity and the thickness of a material used for the fin portions contribute to the heat transport properties. The heat conductivity relates to a velocity at which heat is transported to tip ends of the fin portions and the thickness relates to a heat amount to be dealt with. When used for an apparatus with a high heat generation density, it is desirable that the thermal conductivity of the fin portions is 1200 W/mk or more and the thickness thereof is 100 μm or more. When the thermal conductivity is equal to or higher than 1200 W/mk, heat can be transmitted rapidly to tip ends of the fin portions and heat can be dissipated efficiently. When the thickness is 100 μm or more, a sufficient amount of heat can be dealt with and heat dissipation properties as the heat sink can be improved.

As a material for the fin portions, a graphite material is used. Here, the graphite material is a conductive substance, a laminate or a coating may be formed on surfaces of the fin portions as a countermeasure against dust.

### <Joining Portion>

A joining portion is used tor joining the fin portions to the base portion. Metals can be used as joining materials for forming the joining portion. For example, alloys containing tin (Sn) or titanium (Ti) may be used, but materials are not limited to them. When the joining portion is formed by using a metal joining material which has a lower thermal resistance as compared with other substances, heat in the base portion, can be transmitted to the fin portions efficiently.

As the metal for the joining portion, a joining material containing 0.1 wt % or more and 5 wt % or less of tin, carbon and at least one kind of element (compound forming element) which may form a compound, and containing the balance tin (Sn) as a major component can be used. When the above joining material is used in the present disclosure, an intermetallic compound containing tin, carbon and a compound forming element can be formed between the joining portion and the graphite material forming the fin portions, and the graphite material and the joining portion can be joined more effectively. As the compound forming element, at least one kind of, for example, titanium, zirconium and vanadium can be used, but the element is not limited to them. When the above intermetallic compound is formed in the case where at least one kind of titanium, zirconium and vanadium is used as the compound forming element, the joining portion contains tin, carbon and a compound containing any of titanium, zirconium and vanadium. As the joining portion contains tin, carbon and the compound containing any of titanium, zirconium and vanadium, joining maintains the characteristics of graphite.

In the present specification, “tin, carbon and at least one kind of element (compound forming element) which can form a compound” means tin, carbon and an arbitrary element which forms a compound. When there are two or more compound forming elements, a content (wt %) of the compound forming element in the joining material indicates a ratio of a sum of weights of two kinds or more compound forming elements contained in the joining material with respect to the total weight of the joining material.

In the present specification, the “major component” means an element having the highest abundance ratio in elements contained in

the joining material.

### EXAMPLES

Hereinafter, the embodiment will be specifically explained by citing examples with reference to the drawings. However, the following three examples do not limit the embodiment.

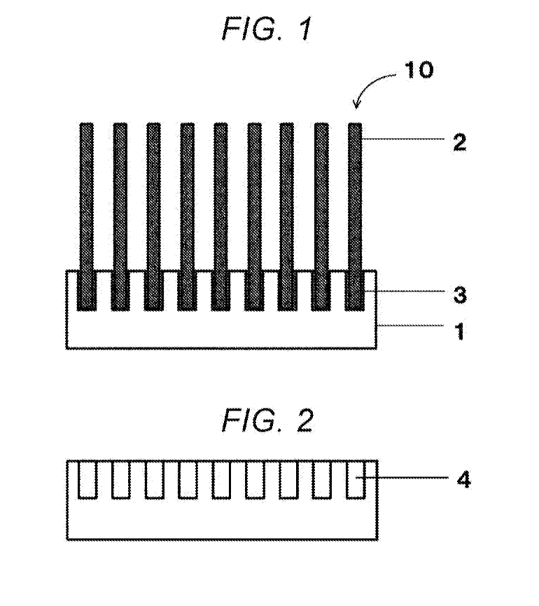

FIG. 1 is a cross-sectional schematic view of a heat sink 10 according to examples 1 to 3 of the present disclosure. The heat sink 10 includes a base portion 1 contacting a heat source, fin portions 2 for dissipating heat and a joining portion 3 joining between the base portion 1 and the fin portions 2. Respective members will be explained in detail below.

### <Base Portion 1>

In Examples 1 to 3, the base portion 1 obtained by processing aluminum was used. Dimensions were 40×40×5 mm, and nine slits 4 with a depth 2 mm were provided as portions into which the fin portions 2 were inserted to have thicknesses of the fin portions 2 at equal intervals. FIG. 2 shows a cross-sectional schematic view showing the base portion 1 provided with the slits 4.

<Fin Portions 2>

In the fin portions 2, a graphite material was fabricated by using a polyimide film of 25 μm (Kapton film manufactured by DU PONT-TORAY CO., LTD) and firing the film at 2800 degrees while under pressure. Three kinds of graphite materials having thicknesses of 100, 300 and 500 μm were fabricated while changing the number of films to be overlapped, which were respectively used as the fin portions 2 as Examples 1, 2 and 3. Dimensions of every surface of the film-shaped fin portions 2 fabricated in Examples 1 to 3 were a depth 40 mm and a width 42 mm, which were inserted into the slits 4 with the depth 2 mm, therefore, portions of 40 mm protruded from upper ends of the film-shaped fin portions 2 to the outside of the base portion 1.

### <Joining Portion 3>

A joining material containing 1.0 wt % of titanium, and the balance tin was used as the joining portion 3 in Examples 1 to 3.

In Examples 1 to 3, manufacture of the heat sink was performed by preparing plurality of fin portions 2 and the base portion 1 having the slits 4 with a width corresponding to a thickness of the plural fin portions 2, pouring the joining material that forms the joining portion 3 into the slits 4 of the base portion 1, inserting the fin portions 2 into the slits 4 and firing the heat sink under a nitrogen environment at a temperature of 600° C.

### (Comparative Examples)

Three heat sinks as comparative examples were manufactured with respect to the above three examples. In Comparative Example 1, the materials for the base portion 1 and the fin portions 2 and the thickness of the fin portions 2 were the same as Example 1, and a heat conductive grease (Shin-Etsu Chemical Co., Ltd., 6-739) was used for the joining portion 3. In Comparative Example 2, materials for the base portion 1, the fin portions 2 and the joining portion 3 were the same as Example 1, and the thickness of the fin portions 2 was set to 80 μm which is thinner than 100 μm of Example 1. In Comparative Example 3, the heat sink was manufactured by performing shaving processing of aluminum which is a method widely used in the past. As the heat sink in Comparative Example 3 was made of a single aluminum piece, the joining portion 3 was not necessary. The thickness of the fin portions 2 in Comparative Example 3 was set to 500 μm, which was the processing lower limit.

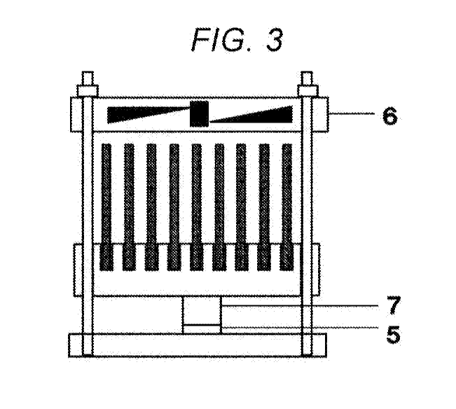

Verification was performed for heat dissipation properties of the obtained heat sinks by using a simple jig. FIG. 3 shows a cross-sectional schematic, view of an effect verification jig. After each heat sink was set in a heating element 5, a FAN 6 was rotated and a temperature of the heating element 5 was measured by using a copper block to which a thermocouple is attached as a temperature measuring unit 7. The present disclosure aims to improve characteristics of the heat sink. It was determined that characteristics of the heat sink was changed when the temperature of the heat source was changed by 2° C. When the temperature of the heat source was reduced by 2° C. as compared with Comparative Example 1, it was determined that the heat dissipation properties were good. When the temperature of the heat source was increased, it was determined that the heat dissipation properties were poor, and when the reduction of temperature was lower than 2° C., it was determined that the properties are average.

Materials of respective members, thermal conductivities and thicknesses of the fin portions 2, results of heat source temperatures and evaluations obtained by the verification of Examples 1 to 3 and Comparative Examples 1 to 3 are shown in the following Table 1.

TABLE 1

| | | | | Comparative | Comparative | Comparative |
|---|---|---|---|---|---|---|
| | Example 1 | Example 2 | Example 3 | Example 1 | Example 2 | Example 3 |
| Base portion | aluminum | aluminum | aluminum | aluminum | Aluminum | aluminum |
| material | | | | | | |
| Fin portion | graphite | graphite | graphite | graphite | Graphite | aluminum |
| material | | | | | | |
| Fin portion | 1200 | 1200 | 1200 | 1200 | 1200 | 230 |
| thermal | | | | | | |
| conductivity | | | | | | |
| [W/mk] | | | | | | |
| Fin portion | 100 | 300 | 500 | 100 | 80 | 500 |
| thickness | | | | | | |
| [μm] | | | | | | |
| Joining | joining | joining | joining | heat | joining | — |
| portion | material | material | material | conductive | material | |
| material | | | | grease | | |
| Heat source | 46 | 45 | 44 | 48 | 48.5 | 50 |
| temperature | | | | | | |
| [° C.] | | | | | | |
| Evaluation | good | good | good | — | Poor | poor |

As a result of comparing the temperature of the heat source in Example 1 with the temperature of the heat source in Comparative Example 1 in Table 1, it was found that the high heat dissipation properties of the heat sink can be realized by joining between the base portion 1 and the fin portions 2 through the metal. It is considered that this is because heat in the base portion 1 is transmitted to the fin portions 2 efficiently as the base portion 1 and the fin portions 2 are joined by a metal with a low thermal resistance.

As a result of comparing Examples 1 to 3 with Comparative Example 2 of Table 1, it is found that improvement effect in heat dissipation properties is not obtained in the case where the thickness of the fin portions 2 is smaller than 100 μm even when metallic joining to the base portion 1 is performed. It is considered that this is because transported heat was reduced as graphite for transporting heat was thin and the neat dissipation properties were not improved significantly.

According to Comparative Example 3 of Table 1, it is found that improvement effect in heat dissipation properties is not obtained in the case where the thermal conductivity of the fin portions 2 is low even when the fin portion 2 has a thickness of 500 μm. It is considered that this is because heat was not capable of being transmitted to tip ends of the tin portions 2 rapidly and heat was not dissipated efficiently as the thermal conductivity of the fin portions 2 was low.

The heat sink fabricated by the manufacturing method, according to the present disclosure has high heat dissipation properties, therefore, the heat sink can be used as a member for countermeasures against heat, for example, in electronic devices such as a server, a personal computer for the server and a projector.

What is claimed is:

1. A graphite heat sink comprising:
plate-shaped fin portions formed of a graphite material;
a base portion contacting lower ends of the plate-shaped fin portions; and
a joining portion between the plate-shaped fin portions and the base portion,
wherein the plate-shaped fin portions have a thermal conductivity of 1200 W/mk or more and a thickness of 100 μm or more, and
the joining portion is formed of metal.

2. The graphite heat sink according to claim 1,
wherein the joining portion is formed of a joining material containing 0.1 wt % or more and 5 w % or less of tin, carbon and at least one kind of element which is capable of forming a compound, and containing the balance of tin (Sn) as a major component.

3. The graphite heat sink according to claim 2,
wherein the at least one kind of element in the joining portion contains at least one kind of titanium, zirconium and vanadium.

4. The graphite heat sink according to claim 3,
wherein a compound containing any of tin, carbon, titanium, zirconium and vanadium is contained in the joining portion.

5. The graphite heat sink according to claim 1,
wherein a compound containing any of tin, carbon, titanium, zirconium, and vanadium is contained in the joining portion.
